(19) United States
(12) Patent Application Publication
(10) Pub. No.: US 2025/0173390 A1
(43) Pub. Date: May 29, 2025

(54) COMPUTER-READABLE RECORDING MEDIUM STORING ARITHMETIC PROGRAM, ARITHMETIC METHOD, AND INFORMATION PROCESSING DEVICE

(71) Applicant: FUJITSU LIMITED, Kawasaki-shi (JP)

(72) Inventors: Norihiko ITANI, Yokohama (JP); Takashi YAMAZAKI, Kawasaki (JP)

(73) Assignee: FUJITSU LIMITED, Kawasaki-shi (JP)

(21) Appl. No.: 19/039,792

(22) Filed: Jan. 29, 2025

Related U.S. Application Data
(63) Continuation of application No. PCT/JP2022/032329, filed on Aug. 29, 2022.

(51) Int. Cl. G06F 17/11

(52) U.S. Cl. CPC G06F 17/11

(57) ABSTRACT

A non-transitory computer-readable recording medium storing an arithmetic program for causing a computer to execute processing includes calculating single-objective optimal solutions that have better values than initial solutions by executing single-objective optimization by using each of a plurality of objective functions as a first evaluation function for the initial solutions, and executing, by using the single-objective optimal solutions as starting points, multi-objective optimization for a second evaluation function by using, as the second evaluation function, a linear weighted sum obtained by performing weighting for each of the plurality of objective functions according to the single-objective optimal solutions.

### CROSS-REFERENCE TO RELATED APPLICATION

This application is a continuation application of International Application PCT/JP2022/032329 filed on Aug. 29, 2022 and designated the U.S., the entire contents of which are incorporated herein by reference.

### FIELD

The present case relates to an arithmetic program, an arithmetic method, and an information processing device.

### BACKGROUND

A technique is disclosed for optimizing a plurality of objective functions such as a production cost or a production completion time when an input order of products to a production line is optimized (for example, refer to Patent Documents 1 to 4).

Japanese Laid-open Patent Publication No. 2022-83200, Japanese Laid-open Patent Publication No. 2002-366587, US Patent Publication No. 2015/0019173, and US Patent Publication No. 2016/0306899 are disclosed as related arts

### SUMMARY

According to an aspect of the embodiments, a non-transitory computer-readable recording medium storing an arithmetic program for causing a computer to execute processing includes calculating single-objective optimal solutions that have better values than initial solutions by executing single-objective optimization by using each of a plurality of objective functions as a first evaluation function for the initial solutions, and executing, by using the single-objective optimal solutions as starting points, multi-objective optimization for a second evaluation function by using, as the second evaluation function, a linear weighted sum obtained by performing weighting for each of the plurality of objective functions according to the single-objective optimal solutions.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram exemplifying Pareto solutions.

FIG. 2 is a diagram exemplifying a case where a genetic algorithm is used for a multi-objective optimization engine.

FIG. 3 is a diagram exemplifying a linear weighted sum method.

FIG. 4A is a functional block diagram representing an overall configuration of an information processing device according to a first embodiment, and FIG. 4B is a hardware configuration diagram of the information processing device.

FIG. 5 is a diagram exemplifying a flowchart of the first embodiment.

FIGS. 6A and 6B are explanatory diagrams of the first embodiment.

FIG. 7 is a diagram exemplifying a flowchart of a second embodiment.

FIGS. 8A and 8B are explanatory diagrams of the second embodiment.

FIG. 9 is a diagram illustrating calculation results.

FIG. 10 is a diagram illustrating calculation results.

FIG. 11 is a diagram for describing a hypervolume.

FIG. 12 is a diagram exemplifying a production line model.

FIGS. 13A to 13C are diagrams exemplifying product information.

FIG. 14 is a diagram illustrating calculation results.

FIG. 15 is a diagram illustrating calculation results.

### DESCRIPTION OF EMBODIMENTS

In a case where multi-objective optimization with a plurality of objective functions set is performed, a solution space widens. Therefore, it involves a long time to start a search from an initial input order as an initial solution and calculate a Pareto optimal solution set that contains candidates for an optimal solution.

In one aspect, an object of the present invention is to provide an information processing device, an arithmetic method, and an arithmetic program that may shorten a calculation time.

There are optimization problems in fields of various industries including a manufacturing industry and a distribution industry. For example, in an optimization problem of a production plan at a manufacturing field, there is a problem that a relationship between a manufacturing time needed for a certain production plan and a cost generated in proportion to an operation time of a device becomes a trade-off. For example, there is a problem of a trade-off that, when the manufacturing time is shortened, an operation time of a legacy device having a high operating cost is increased and a cost is increased, and the like.

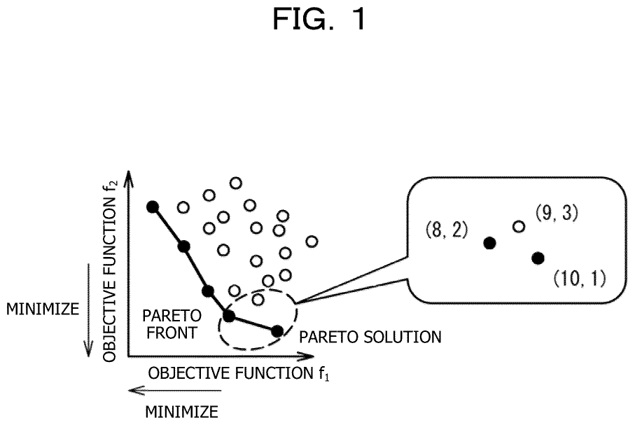

A multi-objective optimization problem for simultaneously optimizing a plurality of objective functions having a trade-off relationship is generally a problem of obtaining a Pareto solution. In the example described above, each of the manufacturing time needed for the certain production plan and the cost generated in proportion to the operation time of the device is the objective function. An explanatory variable is the production plan, and is, for example, an input order in which each product is input to a production process, or the like. The Pareto solution is a solution in which at least one of the plurality of objective functions is superior to those of other optional solutions. FIG. 1 is a diagram exemplifying the Pareto solutions. In FIG. 1, a solution of (f₁, f₂)=(9, 3) is not the Pareto solution since there is no superior objective function when compared with (f₁, f₂)=(8, 2).

In the example of FIG. 1, since optimization is performed so that each objective function is minimized, Pareto solutions positioned on a lower left side are obtained. A line coupling the respective Pareto solutions (arrangement of the respective Pareto solutions) is referred to as a Pareto front. A user selects an optimal solution suitable for a purpose from among the Pareto solutions obtained by multi-objective optimization calculation. Therefore, in order to give a large number of more optimal options to the user, in the multi-objective optimization calculation, it is needed to calculate a more optimal and wider Pareto front in as short a calculation time as possible.

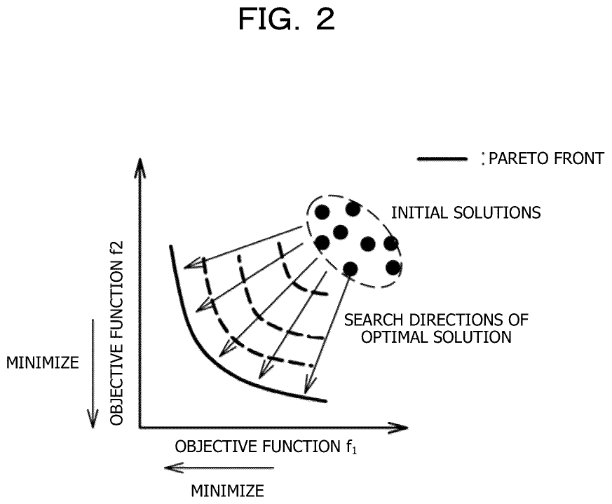

For example, a case is conceivable where a plurality of objective functions desired to be optimized is set to an evaluation function of a multi-objective optimization engine and the multi-objective optimization calculation is performed. FIG. 2 is a diagram exemplifying a case where a genetic algorithm is used as an example for the multi-objective optimization engine. The genetic algorithm is a method of obtaining a solution such that each objective function is minimized from an initial solution group by incorporating genetic elements. In the example of FIG. 2, directions such as moving from initial solutions to a left side and a lower side correspond to search directions. In such a method, it is often not possible to calculate an exact solution in a real time in a real problem having a large problem scale, and thus, it is needed to calculate a more optimal solution in a finite calculation time.

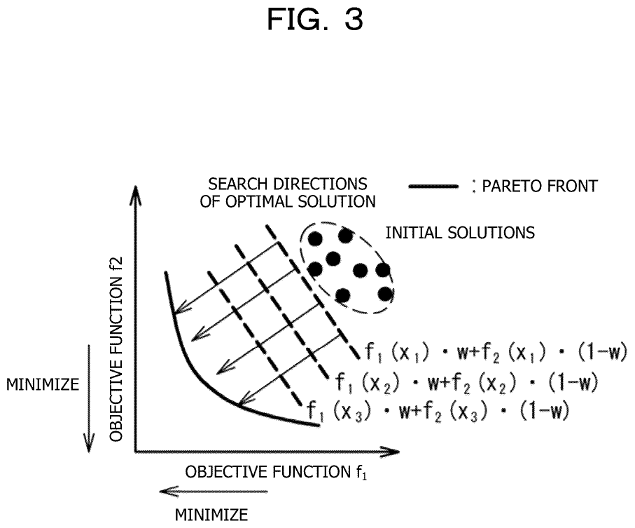

Therefore, a case is conceivable where the plurality of objective functions desired to be optimized is weighted, one evaluation function is set, and optimization calculation is performed with a single-objective optimization engine. FIG. 3 is a diagram exemplifying a linear weighted sum method in this case. For example, an objective function f₁(x₁)·w+an objective function f₂(x₁)·(1−w) is obtained from the initial solution group, an objective function f₁(x₂)·w+an objective function f₂(x₂)·(1−w) is obtained from the solutions, and an objective function f₁(x₃)·w+an objective function f₂(x₃)·(1−w) is further obtained. The reference “w” corresponds to a weight, and is a value that satisfies 0<w<1. However, in such a method, it is difficult to obtain an appropriate weight for a plurality of indexes having different scales as the evaluation function. Furthermore, it is difficult to shorten a calculation time.

Therefore, in the following embodiments, an information processing device, an arithmetic method, and an arithmetic program that may shorten the calculation time will be described.

### First Embodiment

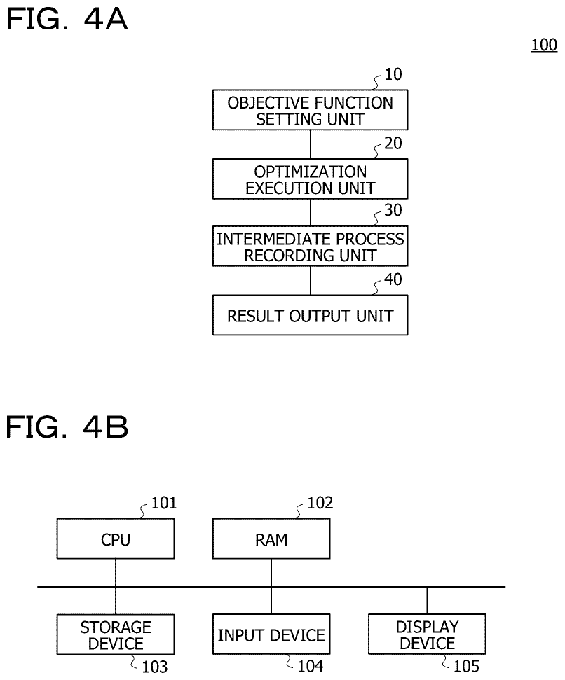

FIG. 4A is a functional block diagram representing an overall configuration of an information processing device 100 according to a first embodiment. The information processing device 100 is a server for optimization processing, or the like. As exemplified in FIG. 4A, the information processing device 100 functions as an objective function setting unit 10, an optimization execution unit 20, an intermediate process recording unit 30, a result output unit 40, and the like.

FIG. 4B is a hardware configuration diagram of the information processing device 100. As exemplified in FIG. 4B, the information processing device 100 includes a CPU 101, a RAM 102, a storage device 103, an input device 104, a display device 105, and the like.

The central processing unit (CPU) 101 is a central processing unit. The CPU 101 includes one or more cores. The random access memory (RAM) 102 is a volatile memory that temporarily stores a program to be executed by the CPU 101, data to be processed by the CPU 101, and the like. The storage device 103 is a nonvolatile storage device. As the storage device 103, for example, a read only memory (ROM), a solid state drive (SSD) such as a flash memory, a hard disk to be driven by a hard disk drive, or the like may be used. The storage device 103 stores an arithmetic program. The input device 104 is a device for a user to input needed information, and is a keyboard, a mouse, or the like. The display device 105 is a device that displays, on a screen, a result output from the result output unit 40, or the like. Each unit of the information processing device 100 is implemented by the CPU 101 executing the arithmetic program. Note that hardware such as a dedicated circuit may be used as each unit of the information processing device 100.

The objective function setting unit 10 sets a plurality of objective functions. The objective function setting unit 10 may set two objective functions or may set three or more objective functions. In the present embodiment, the objective function setting unit 10 sets N objective functions f₁ to f_{N}. The optimization execution unit 20 executes optimization such that the objective functions f₁ to f_{N} are optimized. The intermediate process recording unit 30 records a result in the middle of the execution of the optimization by the optimization execution unit 20. The result output unit 40 outputs the result of the optimization executed by the optimization execution unit 20.

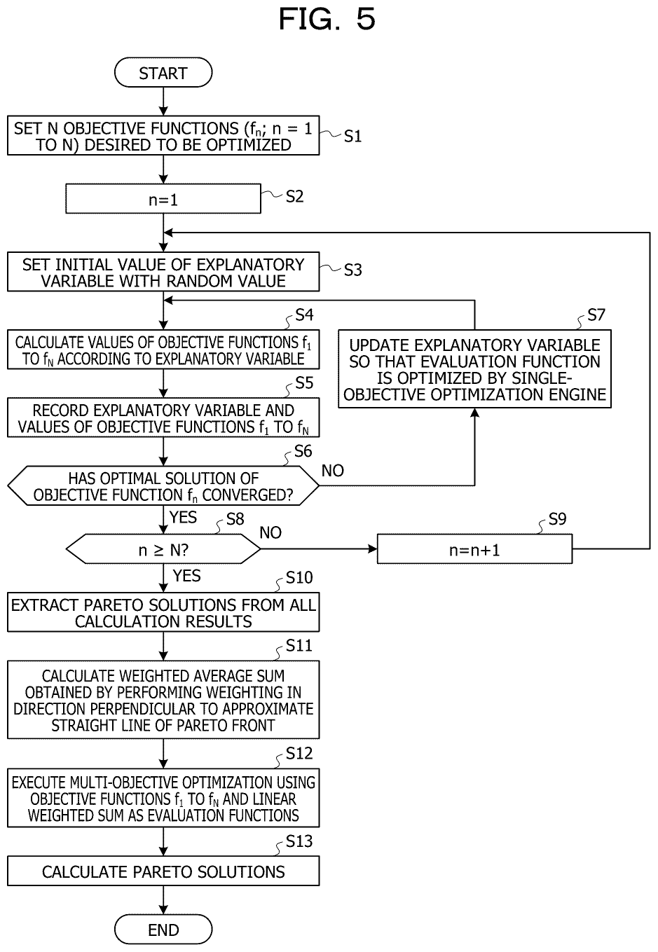

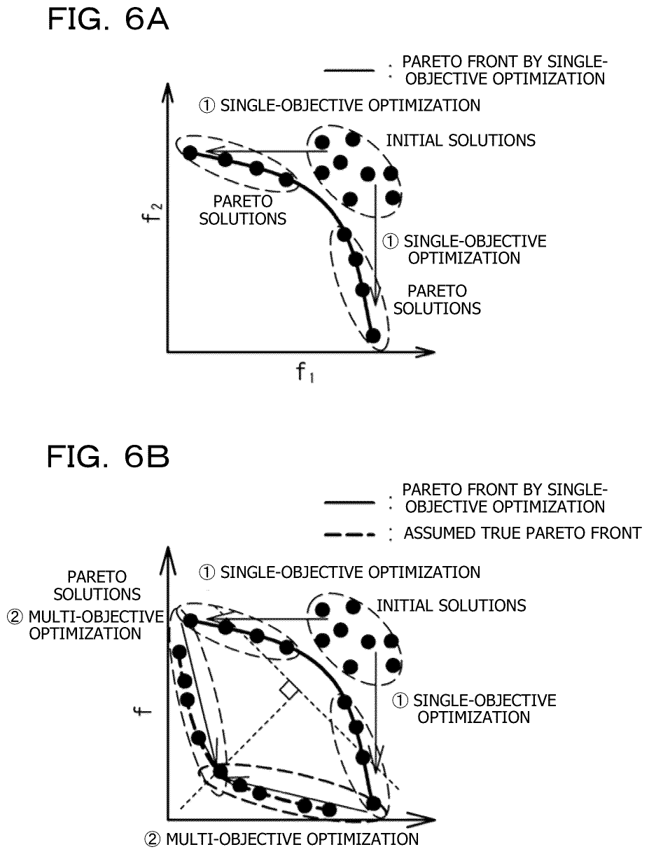

Hereinafter, Pareto optimal solution calculation processing will be described with reference to a flowchart of FIG. 5 and explanatory diagrams of FIGS. 6A and 6B. Note that FIGS. 6A and 6B are explanatory diagrams for the two objective functions f₁ and f₂.

First, the objective function setting unit 10 sets the N objective functions (fₙ; n=1 to N) desired to be optimized (step S1). Each objective function is, for example, a production completion time in a production process, a cost related to production, or the like. A shorter production completion time is better, and a lower cost is better.

Next, the optimization execution unit 20 sets n to 1 (step S2). As a result, first, the objective function f₁ is focused.

Next, the optimization execution unit 20 sets an initial value of each explanatory variable with a random value (step S3). The number of initial values may be one or plural. The initial value may be input by a user using the input device 104.

Next, the optimization execution unit 20 calculates values of the objective functions f₁ to f_{N} according to the explanatory variable (step S4). In a case where step S4 is executed for the first time, the values of the objective functions f₁ to f_{N} are calculated from the initial value of the explanatory variable. In a case where there is a plurality of the initial values, an initial solution group as exemplified in FIG. 6A is generated.

Next, the intermediate process recording unit 30 records the explanatory variable used in step S4 and the values of the objective functions f₁ to f_{N} calculated in step S4 (step S5). Therefore, the intermediate process recording unit 30 records the initial solution group.

Next, the optimization execution unit 20 determines whether or not an optimal solution of the objective function fₙ has converged (step S6). Here, it is determined whether or not the objective function fₙ has reached the best value. Note that it may be determined whether or not a solution better than the initial value has been obtained.

In a case where it is determined as “No” in step S6, the optimization execution unit 20 updates the explanatory variable so that an evaluation function is optimized by a single-objective optimization engine (step S7). Thereafter, step S4 and the subsequent steps are executed again.

In a case where it is determined as “Yes” in step S6, the optimization execution unit 20 determines whether or not n is N or more (step S8). By execution of step S8, it may be determined whether or not single-objective optimization has been ended for all the objective functions.

In a case where it is determined as “No” in step S8, the optimization execution unit 20 adds 1 to n to obtain n+1 (step S9). Thereafter, step S3 and the subsequent steps are executed again.

In a case where it is determined as “Yes” in step S8, the optimization execution unit 20 extracts Pareto solutions from all calculation results (step S10). As a result, as exemplified in FIG. 6A, it is possible to extract Pareto solutions obtained by performing the single-objective optimization on each objective function. Note that the extracted Pareto solutions are recorded by the intermediate process recording unit 30.

Next, the optimization execution unit 20 calculates a linear weighted sum obtained by performing weighting according to arrangement of the Pareto solutions extracted in step S10 (step S11). For example, the weighting is performed in a direction perpendicular to an approximate plane approximating the arrangement of the Pareto solutions. When there are two objective functions, an approximate straight line of the Pareto solutions is used instead of the approximate plane described above. In FIG. 6A, the approximate straight line approximating the Pareto solutions is obtained. An approximation method is not particularly limited, but is, for example, a least squares method or the like. In FIG. 6B, the approximate straight line and a direction intersecting (for example, a direction perpendicular to) the approximate straight line are drawn. This direction corresponds to a search direction of a solution.

Next, the optimization execution unit 20 executes multi-objective optimization using the objective functions f₁ to f_{N} and the linear weighted sum as the evaluation functions (step S12). The initial value of the explanatory variable in this case is the explanatory variable corresponding to the Pareto solutions extracted in step S10.

Next, the optimization execution unit 20 calculates Pareto solutions by using an execution result of step S12 (step S13). The Pareto solutions are drawn in FIG. 6B. Calculation results of step S13 are output by the result output unit 40.

As described above, each of the plurality of N objective functions fₙ(x) (n=1, . . . , N) desired to be optimized is set as the evaluation function of the single-objective optimization, and the optimization is performed by the single-objective optimization engine, and each optimal solution of the single-objective optimization and an explanatory variable thereof are solved. Using each optimal solution of the single-objective optimization as a starting point, the linear weighted sum obtained by weighting each objective function in the direction perpendicular to the Pareto front is set as the evaluation function, and the multi-objective optimization calculation is executed to solve the Pareto solutions. The search direction of the optimal solutions is set with the linear weighted sum while minimizing each objective function to solve the true Pareto front.

In this method, the single-objective optimization is performed on each objective function before the multi-objective optimization. Since the multi-objective optimization is performed using the optimal solutions obtained by the single-objective optimization as the starting points, a calculation time until reaching the true Pareto front is shortened. Note that, since a calculation load of the single-objective optimization is significantly smaller than that of the multi-objective optimization, the calculation load is reduced as a result as compared with a case where the multi-objective optimization is performed without performing the single-objective optimization, and the calculation time may be shortened.

### Second Embodiment

In the first embodiment, a result of an optimal calculation process is used in the single-objective optimization, but the present invention is not limited to this. In a second embodiment, a case will be described where a result of an optimal calculation process is not used in single-objective optimization.

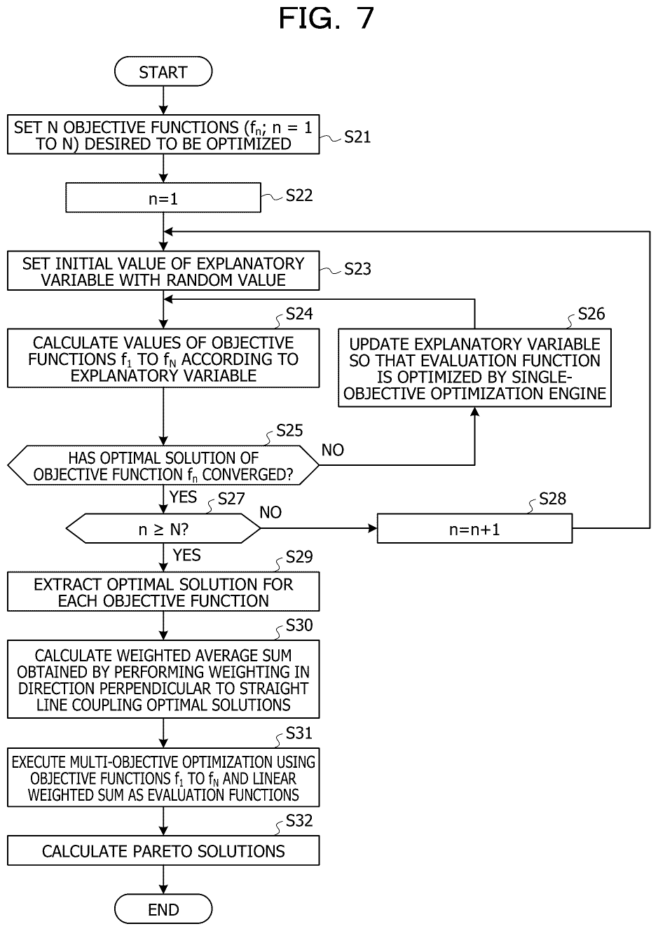

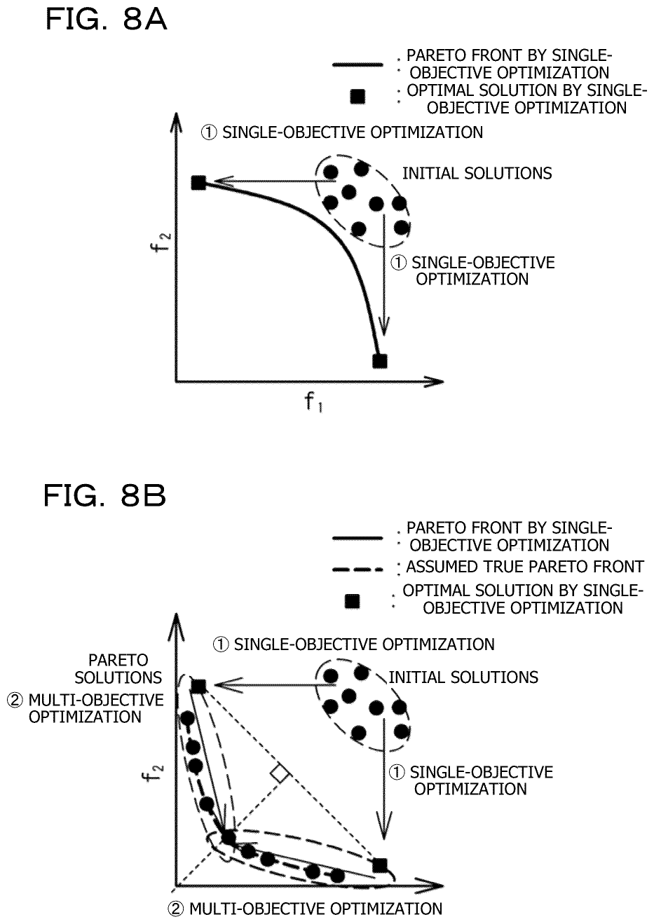

Hereinafter, Pareto optimal solution calculation processing according to the second embodiment will be described with reference to a flowchart of FIG. 7 and explanatory diagrams of FIGS. 8A and 8B. Note that FIGS. 8A and 8B are explanatory diagrams for two objective functions f₁ and f₂.

First, the objective function setting unit 10 sets N objective functions (fₙ; n=1 to N) desired to be optimized (step S21). Each objective function is, for example, a production completion time in a production process, a cost related to production, or the like. A shorter production completion time is better, and a lower cost is better.

Next, the optimization execution unit 20 sets n to 1 (step S22). As a result, first, the objective function f₁ is focused.

Next, the optimization execution unit 20 sets an initial value of an explanatory variable with a random value (step S23). The number of initial values may be one or plural. The initial value may be input by a user using the input device 104.

Next, the optimization execution unit 20 calculates values of the objective functions f₁ to f_{N} according to the explanatory variable (step S24). In a case where step S24 is executed for the first time, the values of the objective functions f₁ to f_{N} are calculated from the initial value of the explanatory variable. In a case where there is a plurality of the initial values, an initial solution group as exemplified in FIG. 8A is generated.

Next, the optimization execution unit 20 determines whether or not an optimal solution of the objective function fₙ has converged (step S25). Here, it is determined whether or not the objective function fₙ has reached the best value. Note that it may be determined whether or not a solution better than the initial value has been obtained.

In a case where it is determined as “No” in step S25, the optimization execution unit 20 updates the explanatory variable so that an evaluation function is optimized by a single-objective optimization engine (step S26). Thereafter, step S24 and the subsequent steps are executed again.

In a case where it is determined as “Yes” in step S26, the optimization execution unit 20 determines whether or not n is N or more (step S27). By execution of step S27, it may be determined whether or not the single-objective optimization has been ended for all the objective functions.

In a case where it is determined as “No” in step S27, the optimization execution unit 20 adds 1 to n to obtain n+1 (step S28). Thereafter, step S23 and the subsequent steps are executed again.

In a case where it is determined as “Yes” in step S27, the optimization execution unit 20 extracts an optimal solution for each objective function (step S29). As exemplified in FIG. 8A, a solution having the lowest value of f₁ and a solution having the lowest value of f₂ are extracted as the optimal solutions. Note that each of the extracted optimal solutions is recorded by the intermediate process recording unit 30.

Next, the optimization execution unit 20 calculates a linear addition sum obtained by performing weighting according to arrangement of the optimal solutions extracted in step S29 (step S30). For example, the weighting is performed in a direction perpendicular to a surface coupling the optimal solutions. When there are two objective functions, a straight line coupling the optimal solutions is used. In FIG. 8A, the straight line coupling the optimal solutions is obtained. In FIG. 8B, the line coupling the optimal solutions and a direction intersecting (for example, a direction perpendicular to) the line are drawn. This direction corresponds to a search direction of a solution.

Next, the optimization execution unit 20 executes multi-objective optimization using the objective functions f₁ to f_{N} and the linear weighted sum as the evaluation functions (step S31). The initial value of the explanatory variable in this case is an explanatory variable corresponding to the optimal solutions extracted in step S29.

Next, the optimization execution unit 20 calculates Pareto solutions by using an execution result of step S31 (step S32). The Pareto solutions are drawn in FIG. 8B. Calculation results of step S32 are output by the result output unit 40.

As described above, each of the plurality of N objective functions fₙ(x) (n=1, . . . , N) desired to be optimized is set as the evaluation function of the single-objective optimization, and the optimization is performed by the single-objective optimization engine, and each optimal solution of the single-objective optimization and an explanatory variable thereof are solved. Using each optimal solution of the single-objective optimization as a starting point, each objective function fₙ and the linear weighted sum obtained by weighting each objective function in the direction perpendicular to a Pareto front are set as the evaluation functions, and the multi-objective optimization calculation is executed to solve the Pareto solutions. The search direction of the optimal solutions is set with the linear weighted sum while minimizing each objective function to solve the true Pareto front.

In this method, the single-objective optimization is performed on each objective function before the multi-objective optimization. Since the multi-objective optimization is performed using the optimal solutions obtained by the single-objective optimization as the starting points, a calculation time until reaching the true Pareto front is shortened. Note that, since a calculation load of the single-objective optimization is significantly smaller than that of the multi-objective optimization, the calculation load is reduced as a result as compared with a case where the multi-objective optimization is performed without performing the single-objective optimization, and the calculation time may be shortened.

### (Simulation Results of First Embodiment)

Hereinafter, simulation results for the first embodiment will be described. As the objective functions, f₁ and f₂ are used. The multi-objective optimization was performed to minimize these objective functions. As an example, a standard problem of the following expression was used. This standard problem is disclosed in “Eckart Zitzler, Kalyanmoy Ded, and Lothar Thiele, Comparison of Multiobjective Evolutionary Algorithms: Empirical Results, Evolutionary Computation, vol. 8, Issue 2, pp. 173?195 (2000).”.

$$𝒥 ( x ) = ( {f}_{1} ( {x}_{1} ) , {f}_{2} ( x ) ) \qquad [ Expression 1 ]$$

The following expressions are used as examples of the objective function f₁ and the objective function f₂.

$${f}_{1} ( {x}_{1} ) = {x}_{1} \qquad [ Expression 2 ]$$

$${f}_{2} ( x ) = g ( {x}_{2} , … , {x}_{m} ) [ 1 - \sqrt{{x}_{1} / g ( {x}_{2} , … , {x}_{m} )} ] \qquad [ Expression 3 ]$$

Here, g(x₂, . . . , xₘ) may be represented as the following expression.

$$g ( {x}_{2} , … , {x}_{m} ) = 1 + 9 ( {\sum }_{i = 2}^{m} {x}_{i} ) / ( m - 1 ) \qquad [ Expression 4 ]$$

Note that it is assumed that m=30 holds and the following expression holds.

$${x}_{i} ∈ [ 0 , 1 ] \qquad [ Expression 5 ]$$

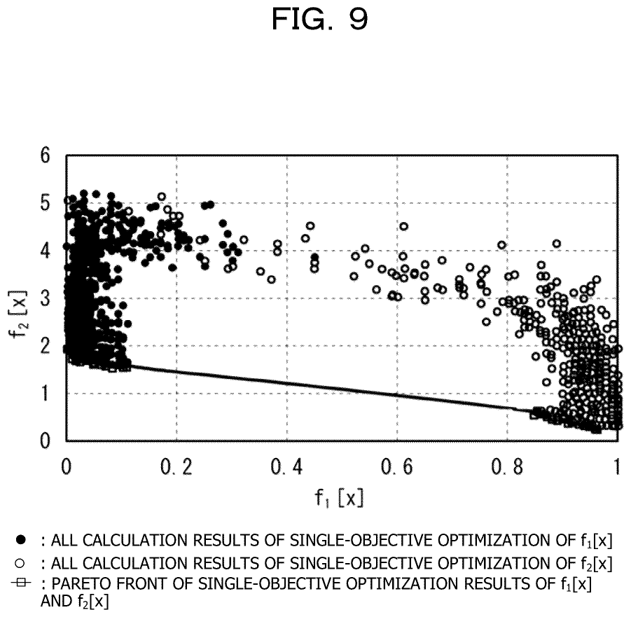

The single-objective optimization was performed for each of the objective functions described above. An explanatory variable x=(x₁, x₂, . . . , x₃₀) with an initial value set with a random value was updated by the single-objective optimization engine to minimize the objective functions. In each single-objective optimization, results of a calculation process (values of the explanatory variable x and f₁(x) and f₂(x)) were also output. Pareto solutions and explanatory variables thereof were obtained from all calculation results including the results of the calculation process of the single-objective optimization. FIG. 9 is a diagram illustrating the calculation results. As illustrated in the results of FIG. 9, in the single-objective optimization, the results are concentrated in a region where the value of f₁(x) is small and a region where the value of f₂(x) is small.

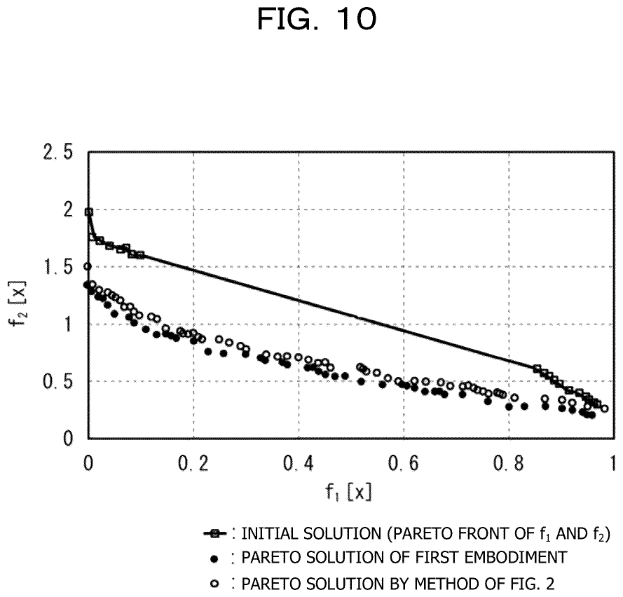

Next, using the Pareto solutions of f₁(x) and f₂(x) as starting points, the multi-objective optimization was performed with three objective functions including a linear weighted sum weighted in a direction perpendicular to an approximate straight line of a Pareto front, f₁(x), and f₂(x). Results are indicated in FIG. 10. In FIG. 10, the Pareto solutions obtained by the method of FIG. 2 are also indicated. When the method of FIG. 2 and the method according to the first embodiment are compared with each other at the same number of times of calculation (about 4900 times), it may be seen that a more optimal Pareto front was able to be calculated by the method according to the first embodiment. Therefore, it may be seen that the calculation time for obtaining the same Pareto front was shortened. When the comparison is performed by using a hypervolume, the hypervolume was 1.3% lower in the method according to the first embodiment than in the method according to FIG. 2.

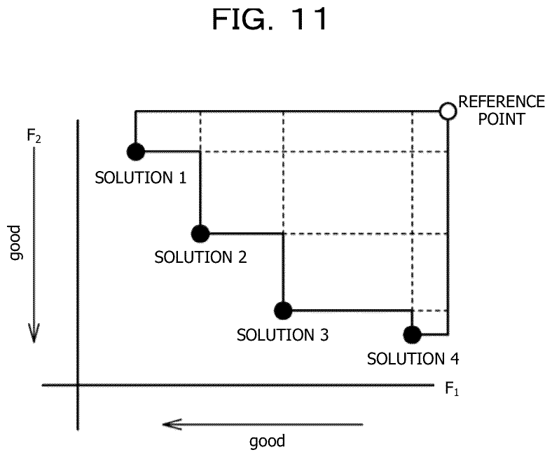

FIG. 11 is a diagram for describing the hypervolume. The hypervolume is a performance index for the Pareto solution. Specifically, the hypervolume represents an area or a volume of a region formed by a certain reference point and a solution set obtained by an algorithm in an objective function space. As an example, it is possible to use a standardized value of each objective function with the reference point of (0, 0). In a case where two objective functions are used, the area represented in FIG. 11 is the hypervolume. As the hypervolume is larger, the solution is wider, so that it may be determined that a favorable result is obtained.

### (Simulation Results of Second Embodiment)

Next, simulation results of the second embodiment will be described. In the second embodiment, the objective function was set using a specific layout of a manufacturing field.

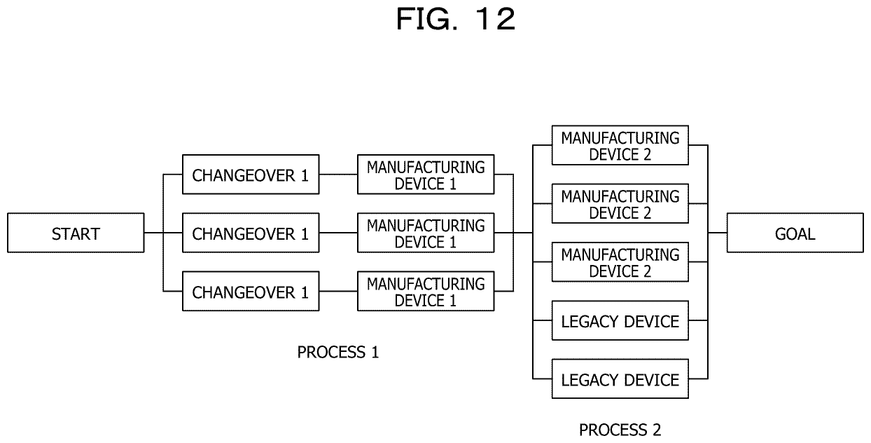

FIG. 12 is a diagram exemplifying a production line model. As exemplified in FIG. 12, the production line model contains branches and merges, and a plurality of products is input one by one. For each of the plurality of products, a plurality of works is performed in order. At least a part of the works are different for the plurality of products.

The production line model in FIG. 12 is a production line model including a process 1 and a process 2. When the process 1 and the process 2 are passed through in accordance with a product input order, branching and merging are repeated, and finally shipping is carried out through inspection and packaging processes. In the process 1, three manufacturing devices 1 with the same specifications are arranged. Before the work is performed in each manufacturing device 1, a changeover (work of changing setting of a jig or a device of a processing machine according to a type of a product to be produced) is performed.

In the process 2, no changeover is needed. In the process 2, three manufacturing devices 2 and two legacy devices with specifications different from those of the manufacturing devices 2 are arranged. The legacy device is a costly and time consuming device.

As an example, there are two changeover workers. Therefore, it is possible to simultaneously perform the changeover in at most two devices in parallel. A cost of each device increases in proportion to an operation time of the device.

With such a layout, as an example, a plan for optimizing a manufacturing time and a cost is made. For example, when it is attempted to shorten the manufacturing time by reducing the changeover, use of the legacy device increases and the cost increases, so that the manufacturing time and the cost are in a trade-off relationship.

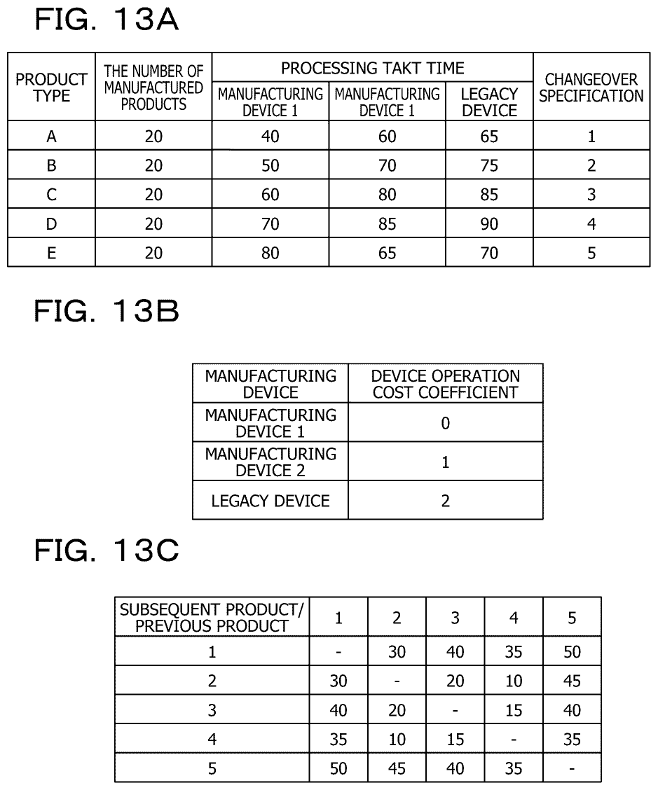

FIGS. 13A to 13C are diagrams exemplifying product information. FIG. 13A is a diagram exemplifying master information in a production master. FIG. 13B is a diagram exemplifying an operation cost in the production master. FIG. 13C is a diagram exemplifying a takt time of a changeover in the production master.

As exemplified in FIG. 13A, the number of manufactured products, a processing takt time of the manufacturing device 1, a processing takt time of the manufacturing device 2, a processing takt time of the legacy device, and a changeover specification are associated with each of product types A to E. As exemplified in FIG. 13B, a device operation cost coefficient is associated with each manufacturing device. The operation cost is calculated by multiplying the processing takt time by the coefficient. As exemplified in FIG. 13C, a changeover takt time is associated with a combination of a subsequent product/a previous product. The previous product for a certain device is a type of a product for which a manufacturing process has been performed in the device so far. The subsequent product is a type of a product for which a manufacturing process is performed next in the device. A number of “subsequent product/previous product” is associated with a combination of the respective products.

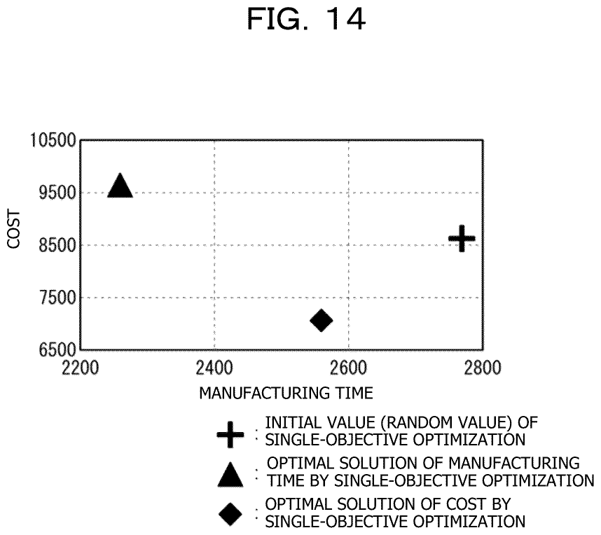

Two objective functions were set: the manufacturing time and the cost. It was assumed that a calculation time was extremely short by using a single-objective solving specialized engine capable of high-speed solving. A random value was set as an initial value. Results are indicated in FIG. 14. A horizontal axis indicates the manufacturing time, and a vertical axis indicates the cost. A single-objective optimal solution is obtained for each of manufacturing time and the cost.

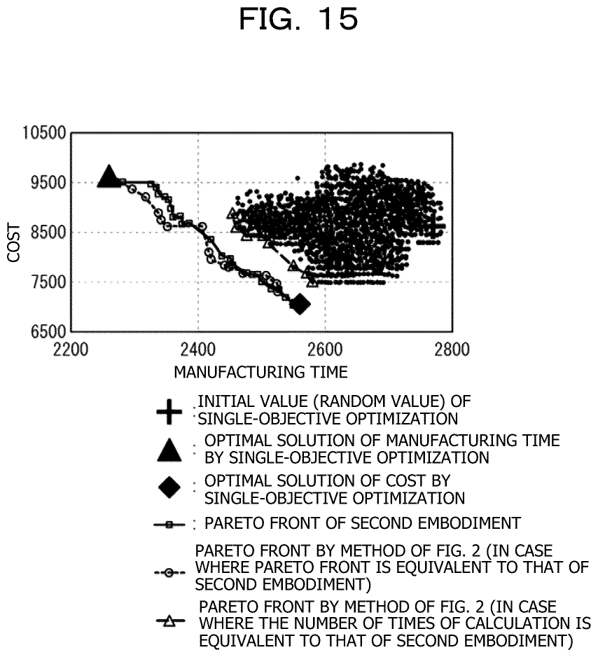

Next, the multi-objective optimization was performed with three objective functions of a linear weighted sum obtained by performing weighting in a direction perpendicular to a straight line coupling optimal solutions, the manufacturing time, and the cost using each single-objective optimal solution of the manufacturing time and the cost as a starting point. Results are indicated in FIG. 15. Since a result (HV=0.576) equivalent to the Pareto front obtained by the method of the second embodiment (the number of times of calculation is about 600) may be obtained by the number of times of calculation of 1600 in the method of FIG. 2, it was possible to reduce a calculation amount by about 60%. Comparing the results of the method of FIG. 2 and the method of the second embodiment with the same number of times of calculation (about 600 times), a wider optimal Pareto front (HV is about twice) was calculated.

Note that, in each of the examples described above, the genetic algorithm is used as an optimization algorithm, but the present invention is not limited to this. Other optimization algorithms such as evolutionary algorithms may be used.

In each of the examples described above, the optimization execution unit 20 is an example of an execution unit that calculates single-objective optimal solutions that have better values than initial solutions by executing single-objective optimization by using each of a plurality of objective functions as a first evaluation function for the initial solutions, and executes, by using the single-objective optimal solutions as starting points, multi-objective optimization for a second evaluation function by using, as the second evaluation function, a linear weighted sum obtained by performing weighting for each of the plurality of objective functions according to the single-objective optimal solutions.

While the embodiments of the present invention have been described above in detail, the present invention is not limited to such specific embodiments, and a variety of modifications and alterations may be made within the scope of the gist of the present invention described in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory computer-readable recording medium storing an arithmetic program for causing a computer to execute processing comprising:
calculating single-objective optimal solutions that have better values than initial solutions by executing single-objective optimization by using each of a plurality of objective functions as a first evaluation function for the initial solutions; and
executing, by using the single-objective optimal solutions as starting points, multi-objective optimization for a second evaluation function by using, as the second evaluation function, a linear weighted sum obtained by performing weighting for each of the plurality of objective functions according to the single-objective optimal solutions.

2. The non-transitory computer-readable recording medium according to claim 1, wherein
the number of the plurality of objective functions is two, and
the computer is caused to execute processing of calculating an approximate straight line approximate to arrangement of the single-objective optimal solutions obtained by the execution of the single-objective optimization and solutions at an intermediate process, and setting the weighting in a direction that intersects the approximate straight line.

3. The non-transitory computer-readable recording medium according to claim 2, wherein the direction that intersects the approximate straight line is a direction perpendicular to the approximate straight line.

4. The non-transitory computer-readable recording medium according to claim 1, wherein
the number of the plurality of objective functions is two, and
the computer is caused to execute processing of setting the weighting in a direction that intersects a line that couples the single-objective optimal solutions obtained by the execution of the single-objective optimization.

5. The non-transitory computer-readable recording medium according to claim 4, wherein the direction that intersects the line that couples the single-objective optimal solutions is a direction perpendicular to the line that couples the single-objective optimal solutions.

6. The non-transitory computer-readable recording medium according to claim 1, wherein
the number of the plurality of objective functions is three or more, and
the computer is caused to execute processing of calculating an approximate plane approximate to arrangement of the single-objective optimal solutions obtained by the execution of the single-objective optimization and solutions at an intermediate process, and setting the weighting in a direction that intersects the approximate plane.

7. The non-transitory computer-readable recording medium according to claim 6, wherein the direction that intersects the approximate plane is a direction perpendicular to the approximate plane.

8. The non-transitory computer-readable recording medium according to claim 1, wherein
the number of the plurality of objective functions is three or more, and
the computer is caused to execute processing of setting the weighting in a direction that intersects a surface that couples the single-objective optimal solutions obtained by the execution of the single-objective optimization.

9. The non-transitory computer-readable recording medium according to claim 8, wherein the direction that intersects the surface that couples the single-objective optimal solutions is a direction perpendicular to the surface that couples the single-objective optimal solutions.

10. An arithmetic method implemented by a computer, the arithmetic method comprising:
calculating single-objective optimal solutions that have better values than initial solutions by executing single-objective optimization by using each of a plurality of objective functions as a first evaluation function for the initial solutions; and
executing, by using the single-objective optimal solutions as starting points, multi-objective optimization for a second evaluation function by using, as the second evaluation function, a linear weighted sum obtained by performing weighting for each of the plurality of objective functions according to the single-objective optimal solutions.

11. An information processing device comprising:
a memory; and
a processor coupled to the memory and configured to
calculating single-objective optimal solutions that have better values than initial solutions by executing single-objective optimization by using each of a plurality of objective functions as a first evaluation function for the initial solutions, and
executing, by using the single-objective optimal solutions as starting points, multi-objective optimization for a second evaluation function by using, as the second evaluation function, a linear weighted sum obtained by performing weighting for each of the plurality of objective functions according to the single-objective optimal solutions.
